(19) United States
(12) Patent Application Publication
(10) Pub. No.: US 2025/0133653 A1
(43) Pub. Date: Apr. 24, 2025

(54) SUBSTRATE STRUCTURE AND MANUFACTURING METHOD THEREOF

(71) Applicant: SILICONWARE PRECISION INDUSTRIES CO., LTD., Taichung City (TW)

(72) Inventor: Tsung-Lung SHEN, Taichung City (TW)

(73) Assignee: SILICONWARE PRECISION INDUSTRIES CO., LTD., Taichung City (TW)

(21) Appl. No.: 18/741,533

(22) Filed: Jun. 12, 2024

(30) Foreign Application Priority Data
Oct. 19, 2023 (TW) 112140031

(51) Int. Cl. H05K 1/02; H01L 21/48; H01L 23/00; H01L 23/498; H05K 1/18

(52) U.S. Cl. CPC H05K 1/0266; H05K 1/181; H01L 21/4857; H01L 21/4867; H01L 23/49838; H01L 24/16; H01L 24/32; H01L 24/73; H01L 2224/16111; H01L 2224/32225; H01L 2224/73204; H01L 2924/152; H05K 2201/09036; H05K 2201/09936

(57) ABSTRACT

A substrate structure and a manufacturing method thereof are provided, in which a substrate body including a dielectric layer and a circuit layer formed on the dielectric layer is provided with a first insulating layer thereon, and a second insulating layer is further provided on the first insulating layer, and a mark is arranged on the second insulating layer. In this way, the arrangement of the mark will not affect wiring space of the circuit layer of the substrate body, and it will not be interfered by the circuit layer when reading the mark, thereby improving the reading success rate.

### BACKGROUND

### 1. Technical Field

The present disclosure relates to a packaging substrate structure, and more particularly, to a substrate structure with marks and a manufacturing method thereof.

### 2. Description of Related Art

In modern life with continuous technological advancement, electronic products play an indispensable role in people's lives. As people's demand for electronic products increases day by day, the identity tracing of electronic products has become more important. One of the current methods of tracing the identity of electronic products is to print marks on the substrate inside the electronic product.

FIG. 1 is a schematic diagram of a conventional substrate structure with a mark. Referring to FIG. 1, a substrate structure 100 has a plurality of contacts 110 and a mark 120. The contacts 110 and the mark 120 are located on a surface 100a of the substrate structure 100, and the contacts 110 are electrically insulated from the mark 120. Next, a chip 200 is disposed on the substrate structure 100. The chip 200 has an active surface 200a and a backside (not shown), wherein the backside of the chip 200 faces the surface 100a of the substrate structure 100. Further, the chip 200 comprises a plurality of bonding pads 210, and the bonding pads 210 are located on the active surface 200a.

However, in the prior art, when designing the substrate structure 100, it is usually necessary to reserve sufficient area on the surface 100a to place the mark 120. The design of the mark 120 often reduces the wiring space of other circuit structures located on the surface 100a of the substrate structure 100. Furthermore, the conventional mark 120 is easily disturbed by the circuit structure, causing the surface to be uneven and making the underlying circuit structure transparent, thus affecting the quality of mark reading and making it difficult to find a suitable location to print the mark.

Therefore, there is a need for a solution that addresses the aforementioned shortcomings in the prior art.

### SUMMARY

In view of the aforementioned shortcomings of the prior art, the present disclosure provides a substrate structure, which comprises: a substrate body including a dielectric layer and a circuit layer formed on the dielectric layer; a first insulating layer disposed on the substrate body and formed with a plurality of openings exposing a portion of the circuit layer; and a second insulating layer disposed on a portion of the first insulating layer, wherein the second insulating layer is arranged with a mark thereon.

The present disclosure also provides a method of manufacturing a substrate structure, the method comprises: providing a substrate body including a dielectric layer and a circuit layer formed on the dielectric layer; disposing a first insulating layer on the substrate body, wherein the first insulating layer is formed with a plurality of openings exposing a portion of the circuit layer; disposing a second insulating layer on a portion of the first insulating layer; and arranging a mark on the second insulating layer.

In the aforementioned substrate structure and method, the mark is made of ink.

In the aforementioned substrate structure and method, the mark is a recess.

In the aforementioned substrate structure and method, the recess is formed on the second insulating layer in a manner of laser ablation.

In the aforementioned substrate structure and method, a depth of the recess is 5 μm to 10 μm.

In the aforementioned substrate structure and method, the mark is text.

In the aforementioned substrate structure and method, the mark is a pattern.

In the aforementioned substrate structure and method, the mark is a two-dimensional barcode pattern.

In the aforementioned substrate structure and method, a vertical projected area of the second insulating layer is stacked on the circuit layer.

As can be understood from the above, in the substrate structure and manufacturing method thereof of the present disclosure, the substrate body including a dielectric layer and a circuit layer formed on the dielectric layer is not only disposed with a first insulating layer, but also disposed with a second insulating layer on the portion of the first insulating layer, and a mark is arranged on the second insulating layer. Therefore, compared with the conventional technique of arranging mark on the same surface of the substrate structure on which the circuit layer is provided, the arrangement of the mark in the present disclosure will not affect the wiring space of the circuit layer of the substrate body, and it will not be interfered by the circuit layer when reading the mark, thereby improving the reading success rate.

### BRIEF DESCRIPTION OF THE DRAWINGS

FIG. 1 is a schematic diagram of a conventional substrate structure with a mark.

FIG. 2A to FIG. 2C-1 are schematic cross-sectional views illustrating a manufacturing method of a substrate structure of the present disclosure.

FIG. 2C-2 is a partially enlarged schematic diagram of a second insulating layer of FIG. 2C-1.

FIG. 3 is a schematic cross-sectional view of an electronic element applying the substrate structure of the present disclosure.

### DETAILED DESCRIPTION

Implementations of the present disclosure are described below by embodiments.

Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

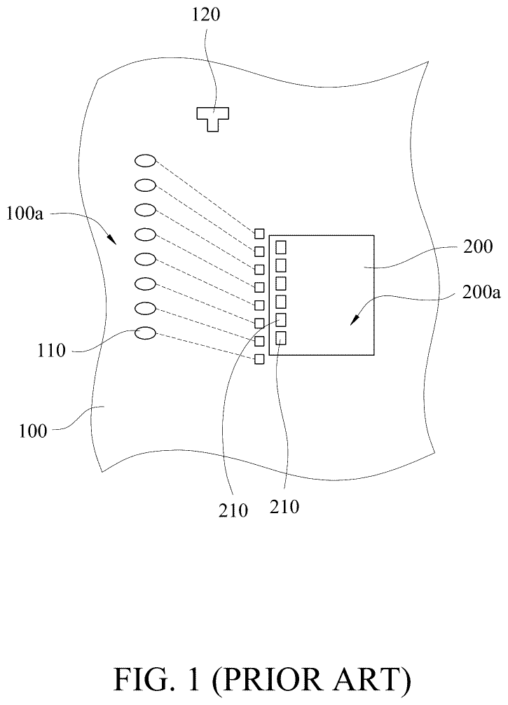

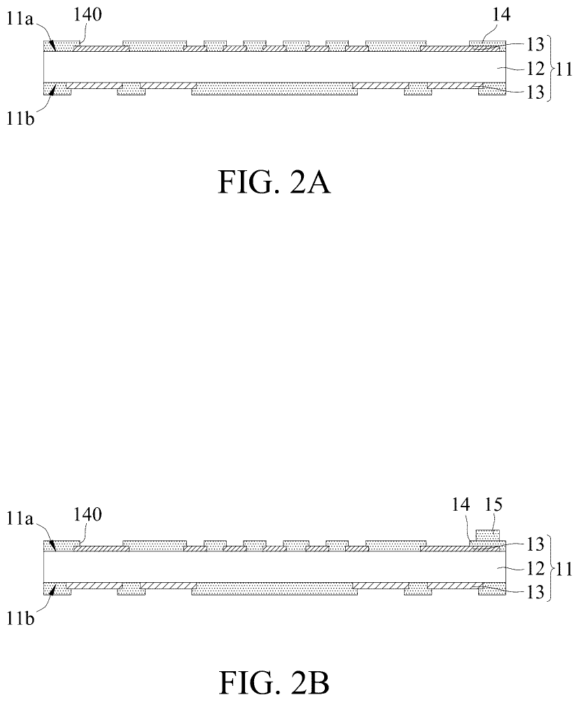

FIG. 2A to FIG. 2C-1 are schematic cross-sectional views illustrating a manufacturing method of a substrate structure of the present disclosure.

First, as shown in FIG. 2A, a substrate body 11 is provided. The substrate body 11 comprises a dielectric layer 12 and a circuit layer 13 formed on the dielectric layer 12. The substrate body 11 has a first side 11a (such as the upper side) and a second side 11b (such as the lower side) opposing the first side 11a, wherein the first side 11a of the substrate body 11 can be used as a chip placement side for carrying electronic elements, and the second side 11b of the substrate body 11 can be used as a ball placement side for sequentially placing solder balls (such as tin balls) and electronic devices (such as circuit boards).

The substrate body 11 is covered with a first insulating layer 14, and the first insulating layer 14 is formed with a plurality of openings 140 for exposing a portion of the circuit layer 13. In an embodiment, the first insulating layer 14 is a solder mask, which can protect the circuit layer 13 bonded therein, avoid short circuits and open circuits due to scratches, and achieve a solder-resist function.

The circuit layer 13 may be made of copper, and the circuit layer 13 may be made by methods such as sputtering, vapor deposition, electroplating, electroless plating, chemical plating, etc., but the present disclosure is not limited to as such.

As shown in FIG. 2B, a second insulating layer 15 is formed on a partial surface of the first insulating layer 14 at the first side 11a of the substrate body 11.

In an embodiment, the second insulating layer 15 is a solder mask. Further, in an embodiment, the first insulating layer 14 and the second insulating layer 15 are formed of the same material, but the present disclosure is not limited to as such. The first insulating layer 14 and the second insulating layer 15 can also be formed of different materials.

Furthermore, on the first insulating layer 14, the second insulating layer 15 can be formed at any position except for the area to be disposed with electronic elements or other elements.

Further, a length of the second insulating layer 15 is, for example, 2.1 mm, a width is, for example, 2.1 mm, and a height is, for example, 15 μm. However, it should be understood that the size of the second insulating layer 15 can be adjusted according to needs to match the size of the mark described later, but the present disclosure is not limited to as such.

As shown in FIG. 2C-1, the second insulating layer 15 is irradiated with laser light (as the arrow shown in FIG. 2C-1) to form a mark 16 on the second insulating layer 15, thereby producing a substrate structure 10 of the present disclosure. Since a vertical projected area of the second insulating layer 15 can be stacked on the circuit layer 13, that is, a position of the second insulating layer 15 is not limited to the distribution position of the circuit layer 13 of the substrate body 11. The mark 16 can be freely arranged at a position convenient for subsequent identification, and there is no need to reserve space to place the mark 16. This ensures that the circuit layer 13 of the substrate body 11 has sufficient wiring space. Therefore, it can have greater flexibility and freedom when designing the substrate structure 10.

Specifically, please refer to FIG. 2C-2, which is a partially enlarged schematic diagram of the second insulating layer in FIG. 2C-1. In an embodiment, the mark 16 is formed in a manner of laser ablation as a recess in the second insulating layer 15 to produce, for example, a two-dimensional barcode (2D code) pattern. Moreover, the overall length of the mark 16 is, for example, 1.6 mm, the width is, for example, 1.6 mm, and the depth is, for example, 5 μm to 10 μm. However, it should be understood that the size of the mark 16 can be adjusted according to needs, but the present disclosure is not limited to as such.

Further, although the mark 16 is a two-dimensional barcode pattern formed by the recess in this embodiment, but the present disclosure is not limited to as such. In other embodiments, text can also be printed on the surface of the second insulating layer 15 in a manner of laser ablation. Alternatively, instead of the laser ablation method, ink can be used to print pattern or text on the surface of the second insulating layer 15, but the present disclosure is not limited to as such.

In addition, the mark 16 may, for example, include information about the identity of the product, or the mark 16 may also record, for example, all relevant processing process records of the substrate structure 10 to trace all current processing processes of the substrate structure 10. When the mark 16 is a two-dimensional barcode pattern, the user can use a scanning device (such as an automatic optical recognition device or a manual scanning device) to identify the mark 16 to obtain relevant information about the product. In the case where the mark 16 is text, the user can directly visually obtain the relevant information of the product.

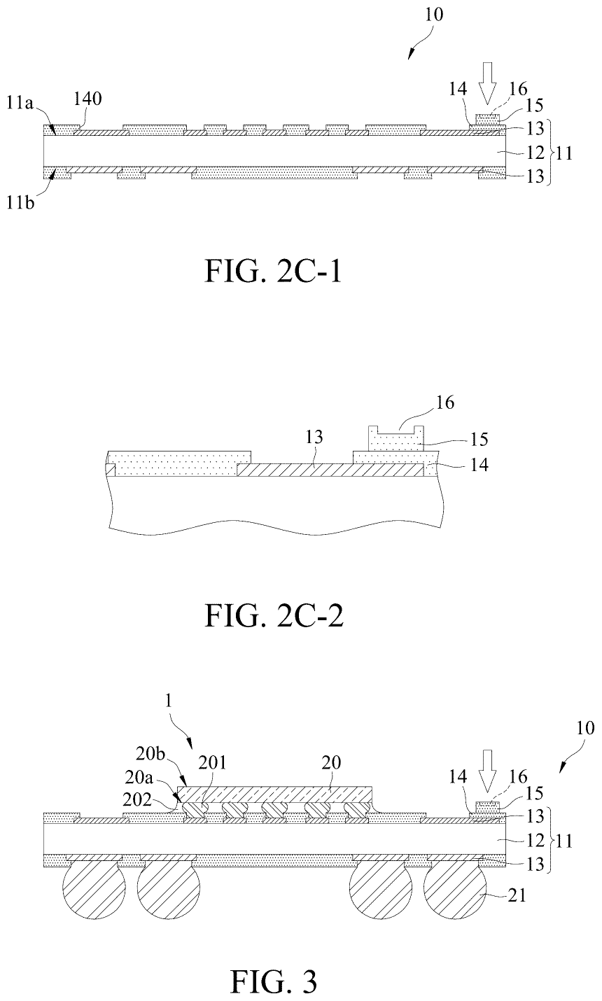

Afterward, as shown in FIG. 3, at least one electronic element 20 is disposed on the first side 11a of the substrate body 11 of the substrate structure 10, and a plurality of conductive elements 21 such as metal pillars of copper pillars, metal bumps covered with insulating blocks, solder balls, solder balls with copper core balls, or other conductive structures are provided on the second side 11b of the substrate body 11 to produce an electronic package 1. Subsequently, the conductive elements 21 can be used to connect to an electronic device such as a circuit board (not shown).

The electronic element 20 may be an active element, a passive element, or a combination of the active element and the passive element. For example, the active element may be a semiconductor chip, and the passive element may be a resistor, a capacitor, or an inductor. In an embodiment, the electronic element 20 can be a semiconductor chip and has an active surface 20a and an inactive surface 20b opposing the active surface 20a. The active surface 20a of the electronic element 20 can have a plurality of electrode pads (not shown), so that the plurality of electrode pads are bonded and electrically connected to the circuit layer 13 of the substrate body 11 in a flip-chip manner via a plurality of conductive bumps 201 made of such as solder material, and then an encapsulating layer such as an underfill 202 is filled between the first side 11a of the substrate body 11 and the active surface 20a of the electronic element 20 to cover the plurality of conductive bumps 201.

In other embodiments, the electronic element 20 can also be electrically connected to the circuit layer of the substrate body 11 via a plurality of bonding wires (not shown); or, the electronic element 20 can directly contact the circuit layer of the substrate body 11. It should be understood that there are many ways for the electronic element 20 to be electrically connected to the substrate structure 10, and the required type and quantity of the electronic element 20 can be connected to the substrate structure 10, but the present disclosure is not limited to as such.

Based on the above, in the manufacturing method of the substrate structure 10 of the present disclosure, there is no need to reserve space for the mark 16 when designing the circuit layer 13 of the substrate body 11, thereby ensuring that the circuit layer 13 has sufficient wiring space, and in actual use, since the mark 16 is formed on the second insulating layer 15 independent of the circuit layer 13 of the substrate body 11, it will not be interfered by the circuit layer 13 of the substrate body 11, thereby improving the reading success rate.

The present disclosure also provides a substrate structure 10 comprising a substrate body 11, a first insulating layer 14 and a second insulating layer 15.

The substrate body 11 comprises a dielectric layer 12 and a circuit layer 13 formed on the dielectric layer 12.

The first insulating layer 14 is disposed on the substrate body 11 and formed with a plurality of openings 140 exposing a portion of the circuit layer 13. The second insulating layer 15 is disposed on a portion of the first insulating layer 14, and the second insulating layer 15 has a mark 16 thereon.

In one embodiment, the mark 16 is made of ink.

In one embodiment, the mark 16 is a recess.

In one embodiment, a depth of the recess is 5 μm to 10 μm.

In one embodiment, the mark 16 is text.

In one embodiment, the mark 16 is a pattern.

In one embodiment, the mark 16 is a two-dimensional barcode pattern.

In one embodiment, a vertical projected area of the second insulating layer 15 is stacked on the circuit layer 13.

In view of the above, in the substrate structure and manufacturing method thereof of the present disclosure, the substrate body including a circuit layer is not only disposed with a first insulating layer, but also disposed with a second insulating layer on the portion of the first insulating layer, and a mark is arranged on the second insulating layer. Therefore, the arrangement of the mark and the circuit layer will not interfere each other, thereby improving the reading success rate.

Furthermore, there is no need to reserve space on the surface to place the mark when designing the substrate structure, which ensures that the circuit layer of the substrate body has sufficient wiring space, and the mark can be arranged at a conveniently identifiable location as required, and its design has great flexibility and freedom.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A substrate structure, comprising:
a substrate body including a dielectric layer and a circuit layer formed on the dielectric layer;
a first insulating layer disposed on the substrate body and formed with a plurality of openings exposing a portion of the circuit layer; and
a second insulating layer disposed on a portion of the first insulating layer, wherein the second insulating layer is arranged with a mark thereon.

2. The substrate structure of claim 1, wherein the mark is made of ink.

3. The substrate structure of claim 1, wherein the mark is a recess.

4. The substrate structure of claim 3, wherein a depth of the recess is 5 μm to 10 μm.

5. The substrate structure of claim 1, wherein the mark is text.

6. The substrate structure of claim 1, wherein the mark is a pattern.

7. The substrate structure of claim 6, wherein the mark is a two-dimensional barcode pattern.

8. The substrate structure of claim 1, wherein a vertical projected area of the second insulating layer is stacked on the circuit layer.

9. A method of manufacturing a substrate structure, comprising:
providing a substrate body including a dielectric layer and a circuit layer formed on the dielectric layer;
disposing a first insulating layer on the substrate body, wherein the first insulating layer is formed with a plurality of openings exposing a portion of the circuit layer;
disposing a second insulating layer on a portion of the first insulating layer; and
arranging a mark on the second insulating layer.

10. The method of claim 9, wherein the mark is made of ink.

11. The method of claim 9, wherein the mark is a recess.

12. The method of claim 11, wherein the recess is formed on the second insulating layer in a manner of laser ablation.

13. The method of claim 11, wherein a depth of the recess is 5 μm to 10 μm.

14. The method of claim 9, wherein the mark is text.

15. The method of claim 9, wherein the mark is a pattern.

16. The method of claim 15, wherein the mark is a two-dimensional barcode pattern.

17. The method of claim 9, wherein a vertical projected area of the second insulating layer is stacked on the circuit layer.
